(19) United States
(12) Patent Application Publication
(10) Pub. No.: US 2017/0125631 A1
(43) Pub. Date: May 4, 2017

(54) SEMICONDUCTOR LIGHT EMITTING DEVICE

(71) Applicant: SAMSUNG ELECTRONICS CO., LTD., Suwon-si (KR)

(72) Inventors: Jin Sub LEE, Suwon-si (KR); Jung Sub KIM, Hwaseong-si (KR); Han Kyu SEONG, Seoul (KR); Soon Jo KWON, Suwon-si (KR); Ji Hye YEON, Cheongju-si (KR); Dong Gun LEE, Hwaseong-si (KR)

(73) Assignee: SAMSUNG ELECTRONICS CO., LTD., Suwon-si (KR)

(21) Appl. No.: 15/235,464

(22) Filed: Aug. 12, 2016

(30) Foreign Application Priority Data
Nov. 3, 2015 (KR) 10-2015-0153825

(51) Int. Cl. H01L 33/06; H01L 33/54; H01L 33/14; H01L 33/62; H01L 33/32; H01L 33/00

(52) U.S. Cl. CPC H01L 33/06; H01L 33/32; H01L 33/0025; H01L 33/145; H01L 33/62; H01L 33/54

(57) ABSTRACT

A semiconductor light emitting device includes a first conductivity-type semiconductor layer; an active layer disposed on the first conductivity-type semiconductor layer, and including: a plurality of quantum barrier layers; and a plurality of quantum well layers containing indium (In), the plurality of quantum barrier layers and the plurality of quantum well layers being alternately stacked on each other, the plurality of quantum well layers comprising a first quantum well layer and a second quantum well layer; and a second conductivity-type semiconductor layer disposed on the active layer, wherein the first quantum well layer is disposed closer to the first conductivity-type semiconductor layer than the second quantum well layer, wherein the second quantum well layer is disposed closer to the second conductivity-type semiconductor layer than the first quantum well layer, wherein a thickness of the second quantum well layer is greater than a thickness of the first quantum well layer, and wherein each of the first and the second quantum well layers comprises at least one graded layer having a varying amount of In composition, and the at least one graded layer of the second quantum well layer has a greater thickness than the at least one graded layer of the first quantum well layer.

### CROSS-REFERENCE TO RELATED APPLICATION

This application claims priority from Korean Patent Application No. 10-2015-0153825, filed on Nov. 3, 2015, with the Korean Intellectual Property Office, the disclosure of which is incorporated herein by reference in its entirety.

### BACKGROUND

1. Field

Apparatuses consistent with example embodiments relate to a semiconductor light emitting device.

2. Description of the Related Art

A semiconductor light emitting device has been known as a next-generation light source having advantages such as a relatively long lifespan, low power consumption, fast response speed, environmental friendliness, and the like. The semiconductor light emitting device has come to prominence as an important light source in various types of products such as lighting devices, backlights of displays, and light sources for electronics. In particular, a nitride-based light emitting device based on a Group III nitride such as GaN, AlGaN, InGaN, or InAlGaN plays an important role in outputting blue or ultraviolet light as a semiconductor light emitting device.

Meanwhile, so-called efficiency droop in which quantum efficiency is decreased as injected current density is increased is pointed out as an issue of a nitride semiconductor based on the Group III nitride. Therefore, a method of improving the quantum efficiency of a semiconductor light emitting device is required in the art.

### SUMMARY

One or more example embodiments of the present inventive concept may provide a semiconductor light emitting device having improved optical output and efficiency droop.

According to example embodiments of the present inventive concept, a semiconductor light emitting device may include: a first conductivity-type semiconductor layer; an active layer disposed on the first conductivity-type semiconductor layer, and including: a plurality of quantum barrier layers; and a plurality of quantum well layers containing indium (In), the plurality of quantum barrier layers and the plurality of quantum well layers being alternately stacked on each other, the plurality of quantum well layers including a first quantum well layer and a second quantum well layer; and a second conductivity-type semiconductor layer disposed on the active layer, wherein the first quantum well layer is disposed closer to the first conductivity-type semiconductor layer than the second quantum well layer, wherein the second quantum well layer is disposed closer to the second conductivity-type semiconductor layer than the first quantum well layer, wherein a thickness of the second quantum well layer is greater than a thickness of the first quantum well layer, and wherein each of the first and the second quantum well layers comprises at least one graded layer having a varying amount of In composition, and the at least one graded layer of the second quantum well layer has a greater thickness than the at least one graded layer of the first quantum well layer.

According to example embodiments of the present inventive concept, a semiconductor light emitting device may include: a first conductivity-type nitride semiconductor layer; an active layer disposed on the first conductivity-type nitride semiconductor layer, and having a plurality of quantum barrier layers including gallium nitride (GaN) and a plurality of quantum well layers including InxGa1-xN (0<x≦1), the plurality of quantum barrier layers and the plurality of quantum well layers alternately stacked on each other, the plurality of quantum well layers including a first quantum well layer and a second quantum well layer; and a second conductivity-type nitride semiconductor layer disposed on the active layer and having an electron blocking layer (EBL) including AlyGa1-yN (0<y≦1), wherein the second quantum well layer is disposed closer to the EBL than the first quantum well layer, wherein each of the first and the second quantum well layers may include: a first graded layer having an increasing amount of an In composition in a direction toward the second conductivity-type semiconductor layer; and a second graded layer having a decreasing amount of an In composition in a direction toward the second conductivity-type semiconductor layer, and wherein at least one of the first graded layer and the second graded layer of the second quantum well layer has a greater thickness than corresponding one of the first graded layer and the second graded layer of the first quantum well layer.

According to example embodiments of the present inventive concept, a semiconductor light emitting device may include: an n-type nitride semiconductor layer; an active layer disposed on the n-type nitride semiconductor layer, and having a plurality of quantum barrier layers including GaN and a plurality of quantum well layers including InxGa1-xN (0<x≦1), the quantum barrier layers and the quantum well layers alternately stacked on each other, the plurality of quantum well layers including a first quantum well layer and a second quantum well layer; and a p-type nitride semiconductor layer disposed on the active layer and having an EBL including AlyGa1-yN (0<y≦1), wherein each of the first and the second quantum well layers includes: a first graded layer; and a second graded layer, and wherein the first graded layer of the second quantum well layer has a band gap decreased in a direction toward the EBL, wherein a second graded layer of the second quantum well layer has an band gap increased in a direction toward the EBL, and wherein at least one of the first graded layer and the second graded layer of the second quantum well layer has a greater thickness than corresponding one of the first graded layer and the second graded layer of the first quantum well layer.

### BRIEF DESCRIPTION OF DRAWINGS

The above and/or other aspects, features, and advantages of the present disclosure will be more clearly understood from the following detailed description taken in conjunction with the accompanying drawings, in which:

FIG. 1 is a schematic cross-sectional view of a semiconductor light emitting device according to an example embodiment of the present inventive concept;

FIG. 2 is an expanded view of region “A” illustrated in FIG. 1;

FIGS. 3 through 6 are schematic views of energy band diagrams around active layers of semiconductor light emitting devices according to an example embodiment of the present inventive concept, respectively;

FIG. 7A is a schematic view of an energy band diagram of a semiconductor light emitting device according to an example embodiment of the present inventive concept;

FIG. 7B is a schematic view of an energy band diagram of a semiconductor light emitting device as a comparative example;

FIGS. 8 through 10 are schematic cross-sectional views of semiconductor light emitting devices according to an example embodiment of the present inventive concept, respectively;

FIG. 11 is a cross-sectional view of a chip-scale light emitting device package including a semiconductor light emitting device according to an example embodiment of the present inventive concept;

FIGS. 12 and 13 are cross-sectional views of light emitting device packages including a semiconductor light emitting device according to an example embodiment of the present inventive concept, respectively;

FIG. 14 is a perspective view of a backlight unit including a semiconductor light emitting device according to an example embodiment of the present inventive concept;

FIG. 15 is a cross-sectional view of a direct-type backlight unit including a semiconductor light emitting device according to an example embodiment of the present inventive concept;

FIG. 16 is a schematic view of a lighting device including a semiconductor light emitting device according to an example embodiment of the present inventive concept;

FIG. 17 is a perspective view of a flat panel lighting device including a semiconductor light emitting device according to an example embodiment of the present inventive concept;

FIG. 18 is an exploded perspective view of a bulb-type lamp including a semiconductor light emitting device according to an example embodiment of the present inventive concept; and

FIG. 19 is an exploded perspective view of a bar-type lamp including a semiconductor light emitting device according to an example embodiment of the present inventive concept.

### DETAILED DESCRIPTION

Hereinafter, example embodiments of the present disclosure will be described as follows with reference to the attached drawings.

The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or substrate, is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the example embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of the present disclosure. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, example embodiments of the present disclosure will be described with reference to schematic views illustrating example embodiments of the present disclosure. In the drawings, for example, due to manufacturing techniques and/or tolerances, modifications of the shape shown may be estimated. Thus, example embodiments of the present disclosure should not be construed as being limited to the particular shapes of regions shown herein, for example, to include a change in shape results in manufacturing. The following example embodiments may also be constituted as one or a combination thereof.

The contents of the present disclosure described below may have a variety of configurations and propose only a required configuration herein, but are not limited thereto.

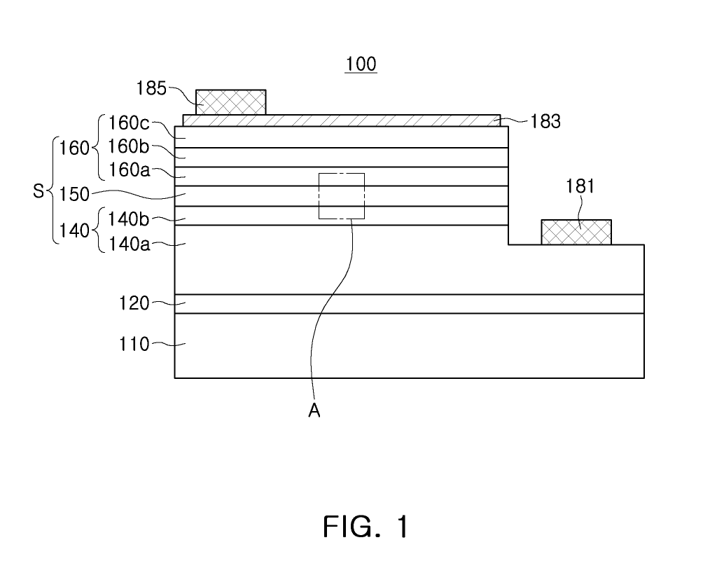

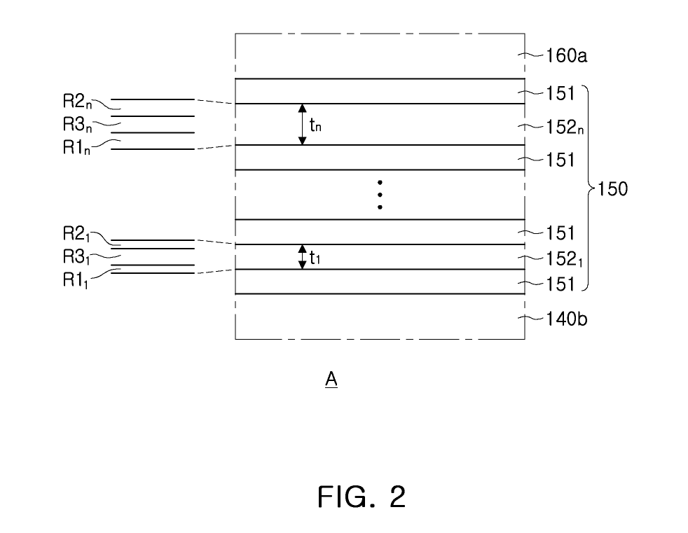

FIG. 1 is a cross-sectional view of a semiconductor light emitting device 100 according to an example embodiment of the present inventive concept. FIG. 2 is an expanded view of region A of FIG. 1.

A semiconductor light emitting device 100 illustrated in FIG. 1 may include a substrate 110, and a first conductivity-type semiconductor layer 140, an active layer 150, and a second conductivity-type semiconductor layer 160 sequentially disposed on the substrate 110 along a thickness direction of a semiconductor light emitting device 100. A buffer layer 120 may be disposed between the substrate 110 and the first conductivity-type semiconductor layer 140. A light emitting stack (S) may include the first conductivity-type semiconductor layer 140, the active layer 150, and the second conductivity-type semiconductor layer 160.

The substrate 110 may be an insulating substrate such as sapphire, MgAl₂O₄, MgO, LiAlO₂, or LiGaO₂. The present inventive concept is not, however, limited thereto, and the substrate 110 may be a conductive substrate or a semiconductor substrate other than the insulating substrate. For example, the substrate 110 may be SiC, Si, or GaN other than sapphire.

The buffer layer 120 may be InₓAl_{y}Ga_{1-x-y}N (0≦x≦1, 0≦y≦1). For example, the buffer layer 120 may be GaN, AlN, AlGaN, or InGaN. If necessary, the buffer layer 12 may be formed by combining a plurality of layers or gradually changing compositions thereof.

The first conductivity-type semiconductor layer 140 may be a nitride semiconductor layer satisfying n-type InₓAl_{y}Ga_{1-x-y}N (0≦x≦1, 0≦y≦1, 0≦x+y<1), and an n-type impurity may be Si. For example, the first conductivity-type semiconductor layer 140 may contain n-type GaN.

In the example embodiment, the first conductivity-type semiconductor layer 140 may include a first conductivity-type contact layer 140a and a current diffusion layer 140b. Impurity concentration of the first conductivity-type contact layer 140a may range from 2×10¹⁸ cm⁻³ to 9×10¹⁹ cm⁻³. A thickness of the first conductivity-type contact layer 140a may range from 1 μm to 5 μm. The current diffusion layer 140b may have a structure in which a plurality of InₓAl_{y}Ga_{1-x-y}N (0≦x, y≦1, 0≦x+y≦1) layers having different compositions or different impurity contents, respectively, are repeatedly stacked along a thickness direction of the current diffusion layer 140b. For example, the current diffusion layer 140b may have an n-type GaN layer having a thickness from 1 nm to 500 nm and/or an n-type superlattice layer in which at least two layers respectively having different compositions of AlₓIn_{y}Ga_{z}N (0≦x,y,z≦1, excluding x=y=z=0) are repeatedly stacked along the thickness direction of the current diffusion layer 140b. An impurity concentration of the current diffusion layer 140b may range from 2×10¹⁸ cm⁻³ to 9×10¹⁹ cm⁻³. If necessary, an additional insulating material layer may be applied to the current diffusion layer 140b.

The second conductivity-type semiconductor layer 160 may be a nitride semiconductor layer satisfying p-type InₓAl_{y}Ga_{1-x-y}N (0≦x<1, 0≦y<1, 0≦x+y<1), and a p-type impurity may be Mg. For example, the second conductivity-type semiconductor layer 160 may be implemented as a single layer structure, but as in the example embodiment, may have a multilayer structure having different compositions. As illustrated in FIG. 1, the second conductivity-type semiconductor layer 160 may include an electron blocking layer (EBL) 160a, a low-concentration p-type GaN layer 160b, and a high-concentration p-type GaN layer 160c. For example, the EBL 160a may have a structure in which a plurality of layers having a thickness from 5 nm to 100 nm and having different compositions of InₓAl_{y}Ga_{1-x-y}N (0≦x≦1, 0≦y≦1, 0≦x+y≦1), respectively, are stacked, or may have a single layer having a composition of Al_{y}Ga_{1-y}N (0≦y≦1). For example, along a thickness of the EBL 160a, an amount of an Al composition of the EBL 160a may be reduced from a portion of the EBL 160a provided close to the active layer 150 toward a portion of the EBL 160a provided farther away from the active layer 150. An energy band gap of the EBL 160a may be reduced from a portion of the EBL 160a provided close to the active layer 150 toward a portion of the EBL 160a provided farther away from the active layer 150.

The active layer 150 formed on the first conductivity-type semiconductor layer 140 may have a multiple quantum well (MQW) structure in which a plurality of quantum barrier layers 151 and a plurality of quantum well layers 152 (152₁ . . . 152ₙ) are alternately stacked on each other along a thickness direction of the active layer 150. For example, the quantum barrier layers 151 and the quantum well layers 152 (152₁ . . . 152ₙ) may be InₓAl_{y}Ga_{1-x-y}N (0≦x≦1, 0≦y≦1, 0≦x+y≦1) having different compositions. In the example embodiment, the quantum well layers 152 (152₁ . . . 152ₙ) may be InₓGa₁₋ₓN (0<x≦1), and the quantum barrier layers 151 may be GaN. A thickness of each of the quantum barrier layers 151 may range from 1 nm to 50 nm, and a thickness of each of the quantum well layers 152 (152₁ . . . 152ₙ) may also range from 1 nm to 50 nm.

The semiconductor light emitting device 100 may include a first electrode 181 disposed on a region of the first conductivity-type semiconductor layer 140, and an ohmic contact layer 183 and a second electrode 185 sequentially disposed on the second conductivity-type semiconductor layer 160.

The first electrode 181 is not limited thereto, and may contain a material such as Ag, Ni, Al, Cr, Rh, Pd, Ir, Ru, Mg, Zn, Pt, or Au, and may be employed as a structure having a single layer or two or more layers. The first electrode 181 may further include a pad electrode layer disposed thereon. The pad electrode layer may include at least one of materials such as Au, Ni, and Sn.

The ohmic contact layer 183 may include a light transmitting electrode. The light transmitting electrode may be one of a transparent conductive oxide layer or a nitride layer. For example, the light emitting electrode may contain at least one selected from indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In4Sn₃O₁₂, and zinc magnesium oxide (Zn₁₋ₓMgₓO) (0≦x≦1). If necessary, the ohmic contact layer 183 may also contain graphene. The ohmic contact layer 183 may be implemented in various ways according to chip structures. For example, when the ohmic contact layer 183 has a flip-chip structure, the ohmic contact layer 183 may include a metal such as Ag, Au, or Al, and a transparent conductive oxide such as ITO, ZIO, or GIO. The second electrode 185 may contain at least one of Al, Au, Cr, Ni, Ti, and Sn.

Referring to FIG. 2, the quantum well layers 152 (152₁ . . . 152ₙ) of the example embodiment will be described in more detail. Each of the quantum well layers 152 (152₁ . . . 152ₙ) may include a first graded layer R1 (R1₁ . . . R1ₙ) having an increasing amount of the In composition in a direction toward the second conductivity-type semiconductor layer 160 along a thickness direction of the first graded layer R1 (R1₁ . . . R1ₙ), a second graded layer R2 (R2₁ . . . R2ₙ) having a decreasing amount of the In composition in the direction toward the second conductivity-type semiconductor layer 160 along a thickness direction of the second graded layer R2 (R2₁ . . . R2ₙ), and an internal quantum well layer R3 (R3₁ . . . R3ₙ) disposed between the first graded layer R1 and the second graded layer R2. A thickness tₙ of the quantum well layer 152ₙ adjacent to the second conductivity-type semiconductor layer 160 may be greater than a thickness t₁ of the quantum well layer 152₁ adjacent to the first conductivity-type semiconductor layer 140.

Here, a thickness of each of the first and second graded layers R1ₙ and R2ₙ of the quantum well layer 152ₙ adjacent to the second conductivity-type semiconductor layer 160 may be the greatest, and a thickness of each of the first and second graded layers R1₁ and R2₁ of the quantum well layer 152₁ adjacent to the first conductivity-type semiconductor layer 140 may be the thinnest. Each quantum well layer 152 (152₁ . . . 152ₙ) may have the first graded layer R1 (R1₁ . . . R1ₙ) and the second graded layer R2 (R2₁ . . . R2ₙ) having the same thickness as each other. For example, the thickness of the first graded layer R1₁ and the second graded layer R2₁ of the quantum well layer 152₁ have the same thickness as each other and the thickness of the first graded layer R1ₙ and the second graded layer R2ₙ of the quantum well layer 152ₙ have the same thickness as each other.

In an example embodiment, in comparing a thickness of each of the quantum well layers 152 along a thickness direction of the quantum well layer 152, the thickness of each quantum well layer may increase with respect to an adjacent quantum well layer as the quantum well layer is provided at a position closer to the second conductivity-type semiconductor layer 160. That is, the following condition is met:

tₙ of 152ₙ> . . . >t₂ of 152₂>t₁ of 152₁

Here, the thicknesses of the first and second graded layers R1 (R1₁ . . . R1ₙ) and R2 (R2₁ . . . R2ₙ) of the respective quantum well layer 152 (152₁ . . . 152ₙ) may increase with respect to an adjacent quantum well layer as the first and second graded layers R1 (R1₁ . . . R1ₙ) and R2 (R2₁ . . . R2ₙ) are provided at a position closer to the second conductivity-type semiconductor layer 160. That is, the following condition is met:

thicknesses of R1ₙ and R2ₙ> . . . >thicknesses of R1₂ and R2₂>thicknesses of R1₁ and R2₁

The first graded layer R1 (R1₁ . . . R1ₙ) and the second graded layer R2 (R2₁ . . . R2ₙ) may have the same thickness as each other. That is, the following condition is met:

a thickness of R1ₙ=a thickness R2ₙ, a thickness of R1₁=a thickness R2₁

Each quantum well layer 152 may further include an internal quantum well layer R3 having a constant In composition and disposed between the first graded layer R1 and the second graded layer R2.

A thickness of each of the internal quantum well layers R3 (R3₁ . . . R3ₙ) disposed between the first conductivity-type semiconductor layer 140 and the second conductivity-type semiconductor layer 160 along a thickness direction of the active layer 150 may be constant. For example, the thickness of the internal quantum well layer R3ₙ of the quantum well layer 152ₙ adjacent to the second conductivity-type semiconductor layer 160 may be substantially the same as that of the internal quantum well layer R3₁ of the quantum well layer 152₁ adjacent to the first conductivity-type semiconductor layer 140. However, the example embodiment is not limited thereto. In a different manner, in an example embodiment, the thickness of the internal quantum well layer R3ₙ adjacent to the second conductivity-type semiconductor layer 160 may be smaller than the quantum well layer 152₁ adjacent to the first conductivity-type semiconductor layer 140. In addition, the thickness of the internal quantum well layers R3 (R3₁ . . . R3ₙ) may gradually decrease as a respective position of the internal quantum well layer R3 (R3₁ . . . R3ₙ) gets closer to the second conductivity-type semiconductor layer 160. For example, the thickness of the internal quantum well layer R3ₙ of the quantum well layer 152ₙ adjacent to the second conductivity-type semiconductor layer 160 may be smaller than that of the internal quantum well layer R3₁ of each quantum well layer 152₁ adjacent to the first conductivity-type semiconductor layer 140.

The quantum well layer 152ₙ provided closest to the second conductivity-type semiconductor layer 160 may have the first and second graded layers R1ₙ and R2ₙ having the thicknesses greater than that of the internal quantum well layer R3ₙ. The quantum well layer 152₁ provided closest to the first conductivity-type semiconductor layer 140 may also have the first and second graded layers R1₁ and R2₁ having the thicknesses smaller than that of the internal quantum well layer R3₁.

As such, a method of adjusting the thicknesses of the first and second graded layers R1 (R1₁ . . . R1ₙ) and R2 (R2₁ . . . R2ₙ) of each quantum well layer 152 (152₁ . . . 152ₙ) may allow the quantum well layer 152₁ adjacent to the first conductivity-type semiconductor layer 140 to have a smaller thickness, thereby reducing crystal defects that may occur in a process of reducing strain in a lower region of the active layer 150 adjacent to the first conductivity-type semiconductor layer 140, and may allow the quantum well layers 152ₙ adjacent to the second conductivity-type semiconductor layer 160 to have a greater thickness, thereby reducing an internal electric field generated by piezoelectric polarization in an upper region of the active layer 150 adjacent to the second conductivity-type semiconductor layer 160 having improved recombination efficiency. The reduction in the internal electric field caused by the piezoelectric polarization may allow efficiency droop of the semiconductor light emitting device 100 to be improved.

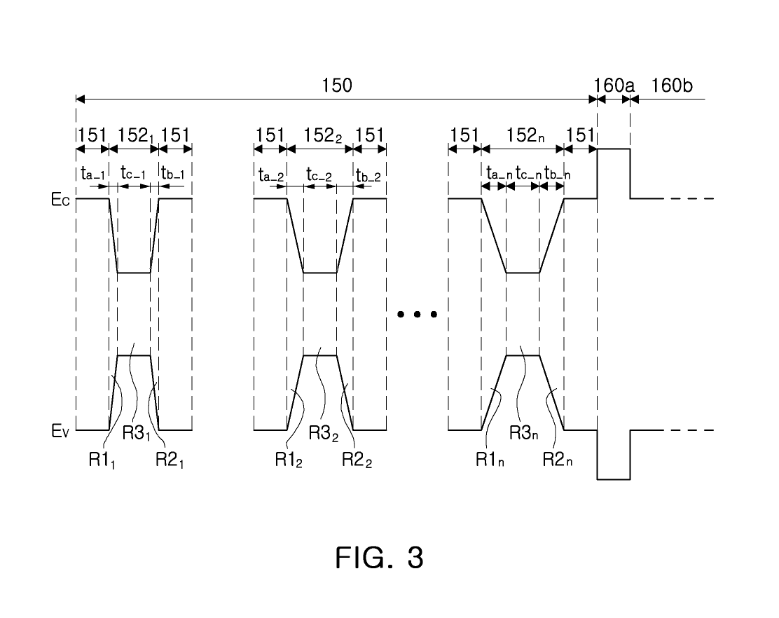

FIGS. 3 through 6 are schematic views of energy band diagrams around active layers of semiconductor light emitting devices according to example embodiments of the present inventive concept. In the energy band diagrams respectively illustrated in FIGS. 3 through 6, an internal electric field generated by self-polarization and piezoelectric polarization is not considered for convenience.

FIG. 3 is a schematic view of an energy band diagram around an active layer 150 of a semiconductor light emitting device 100 according to an example embodiment of the present inventive concept.

Referring to FIG. 3, each of quantum well layers 152 (152₁, 152₂ . . . 152ₙ) may include a first graded layer R1 (R1₁, R1₂ . . . R1ₙ) having an energy band gap decreased in a direction toward an EBL 160a, a second graded layer R2 (R2₁, R2₂ . . . R2ₙ) having an energy band gap increased in a direction toward the EBL 160a, and an internal quantum well layer R3 (R3₁, R3₂ . . . R3ₙ) disposed between the respective first graded layer R1 (R1₁, R1₂ . . . R1ₙ) and the respective second graded layer R2 (R2₁, R2₂ . . . R2ₙ) and having a constant energy band gap. In the example embodiment, the first graded layer R1 (R1₁, R1₂ . . . R1ₙ) and the second graded layer R2 (R2₁, R2₂ . . . R2ₙ) may have respective shapes of energy bands thereof symmetrical to each other around the internal quantum well layer R3.

The energy band (for example, a conduction band) of each of the first graded layers R1 (R1₁, R1₂ . . . R1ₙ) may have a first slope at which the energy band gap is decreased in the direction toward the EBL 160a, the energy band of each of the second graded layers R2 (R2₁, R2₂ . . . R2ₙ) may have a second slope at which the energy band gap is increased in the direction toward the EBL 160a, and the first slope and the second slope may be reduced as the first graded layer R1 (R1₁, R1₂ . . . R1ₙ) and the second graded layer R2 (R2₁, R2₂ . . . R2ₙ) are closer to the EBL 160a. That is, the rate of change in the increase of the energy band gap and the rate of change in the decrease of the energy band gap is reduced as the first graded layer R1 (R1₁, R1₂ . . . R1ₙ) and the second graded layer R2 (R2₁, R2₂ . . . R2ₙ) are closer to the EBL 160a. Here, an absolute value of each of the first and second slopes may be the same as each other. A thickness tₐ (tₐ_{_}₁, tₐ_{_}₂, . . . , tₐ_{_}₂) of the first graded layer R1 (R1₁, R1₂ . . . R1ₙ) and a thickness t_{b} (t_{b}_{_}₁, t_{b}_{_}₂, . . . , t_{b}_{_}₂) of the second graded layer R2 (R2₁, R2₂ . . . , R2ₙ) may be greater as the first graded layer R1 and the second graded layer R2 are closer to the EBL 160a. That is, the following conditions are met:

tₐ_{_}₁<tₐ_{_}₂< . . . <tₐ_{_}ₙ and t_{b}_{_}₁<t_{b}_{_}₂< . . . <t_{b}_{_}ₙ

Because the energy band gaps are changed depending on the In compositions, slopes of the In compositions of the first and second graded layers R1 and R2 may be reduced as the first and second graded layers R1 and R2 are closer to the EBL 160a. The slopes of the In compositions of the first and second graded layers R1ₙ and R2ₙ of the quantum well layer 152ₙ adjacent to the EBL 160a may be smaller than the slopes of the In compositions of the first and second graded layers R1₁ and R2₁ of the quantum well layer 152₁ adjacent to a first conductivity-type semiconductor layer 140.

The first and second graded layers R1 (R1₁, R1₂ . . . R1ₙ) and R2 (R2₁, R2₂ . . . R2ₙ) of which the energy band gaps are changed may be formed by forming quantum barrier layers 151 including GaN and then adjusting an input amount of an In source gas or a growth temperature in a process of forming the quantum well layers 152 including InₓGa₁₋ₓN (0<x≦1). In more detail, in an initial growth process of a single quantum well layer 152, the first graded layer R1 may be formed by lowering the growth temperature while maintaining a constant input amount of the In source gas, or by increasing the input amount of the In source gas while maintaining a constant growth temperature. In a late growth process of the single quantum well layer 152, the second graded layer R2 may be formed by raising the growth temperature while maintaining a constant input amount of the In source gas, or by decreasing the input amount of the In source gas while maintaining a constant growth temperature. Circumstances may allow the growth temperature and the input amount of the In source gas to be adjusted together, thereby forming the first and second graded layers R1 and R2. Meanwhile, after the formation of the first graded layer R1, the internal quantum well layer R3 may be formed by inputting a predetermined amount of the In source gas at a constant temperature before the second graded layer R2 is formed.

Therefore, when each quantum well layer 152 included in an active layer 150 is formed, growth thicknesses and In compositions of the first and second graded layers R1 and R2 may be adjusted to change the first and second slopes of the energy bands of the first and second graded layers R1 (R1₁, R1₂ . . . R1ₙ) and R2 (R2₁, R2₂ . . . R2ₙ) as the first and second graded layers R1 and R2 are closer to the EBL 160a.

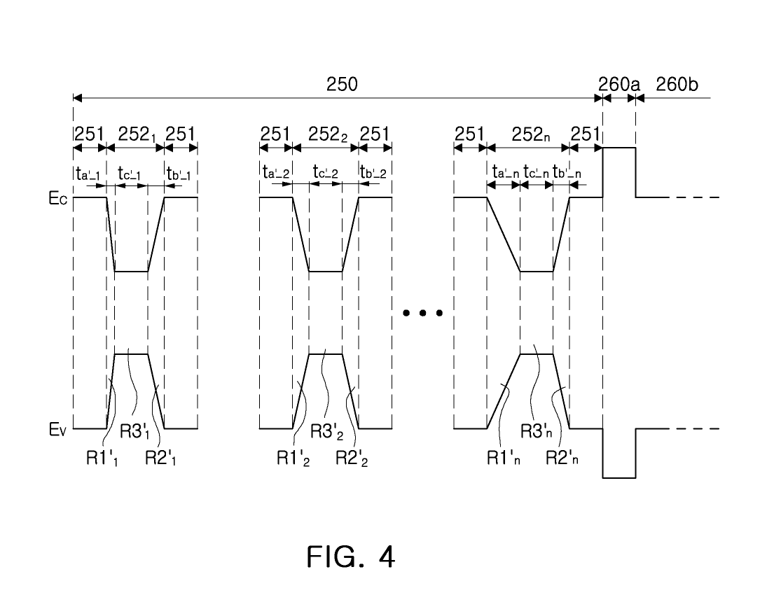

FIG. 4 is a schematic view of an energy band diagram around an active layer 250 of a semiconductor light emitting device 100 according to an example embodiment of the present inventive concept. FIG. 4 is an example of a structure of each of quantum well layers 252 (252₁, 252₂ . . . 252ₙ) within an active layer 250, the structure modified from that of each of the quantum well layers 152 within the active layer 150 of the semiconductor light emitting device illustrated in FIG. 3.

Referring to FIG. 4, unlike the example embodiment illustrated in FIG. 3, the active layer 250 may include a plurality of quantum barrier layers 251 (251₁, 251₂ . . . 251ₙ) and a plurality of quantum well layers 252 (252₁, 252₂ . . . 252ₙ), and each of the quantum well layers 252 (252₁, 252₂ . . . 252ₙ) may include a first graded layer R1′ having an energy band gap decreased in a direction toward an EBL 260a, a second graded layer R2′ having an energy band gap increased in the direction toward the EBL 260a, and an internal quantum well layer R3′ disposed between the first graded layer R1′ and the second graded layer R2′ and having a constant energy band gap. An energy band (for example, a conduction band) of the first graded layer R1′ may have a first slope at which the energy band gap is decreased in the direction toward the EBL 260a, an energy band of the second graded layer R2′ may have a second slope at which the energy band gap is increased in the direction toward the EBL 260a, and the first slope may be reduced and the second slope may be maintained as the first graded layer and the second graded layer are closer to the EBL 260a.

A thickness tₐ′ of the first graded layer R1′ may be greater as the first graded layer R1′ is closer to the EBL 260a, and a thickness t_{b}′ of the second graded layer R2′ may be constant. The thickness t_{a′}_{_}ₙ of the first graded layer R1ₙ′ of the quantum well layer 252 adjacent to the EBL 260a may be greatest, and the thickness t_{a′}_{_}₁ of the first graded layer R1₁′ of each quantum well layer 152 adjacent to a first conductivity-type semiconductor layer may be thinnest. As the first and second graded layers R1′ and R2′ are closer to the EBL 260a, a slope of an In composition of the first graded layer R1′ may be reduced, and a slope of an In composition of the second graded layer R2′ may be constant. That is, the following conditions may be met:

t_{a′}_{_}₁<t_{a′}_{_}₂< . . . <t_{a′}_{_}ₙ,t_{b′}_{_}₁=t_{b′}_{_}₂= . . . =t_{b′}_{_}ₙ and t_{c′}_{_}₁=t_{c′}_{_}₂= . . . =t_{c′}_{_}ₙ

The present inventive concept is not limited thereto, and unlike those illustrated in FIG. 4, in an example embodiment, the second slope may be reduced, and the first slope may be maintained as the first graded layer R1′ is closer to the EBL 260a. The thickness t_{b}′ of the second graded layer R2′ may be greater as the second graded layer R2′ is closer to the EBL 260a, and the thickness tₐ′ of the first graded layer R1′ may be constant. That is, the following conditions may be met:

t_{a′}_{_}₁=t_{a′}_{_}₂= . . . =t_{a′}_{_}ₙ,t_{b′}_{_}₁<t_{b′}_{_}₂ . . . <t_{b′}_{_}ₙ and t_{c′}_{_}₁=t_{c′}_{_}₁=t_{c′}_{_}₂= . . . =t_{c′}_{_}ₙ

As the first and second graded layers R1′ and R2′ are closer to the EBL 260a, the slope of the In composition of the second graded layer R2′ may be reduced, and the slope of the In composition of the first graded layer R1′ may be constant.

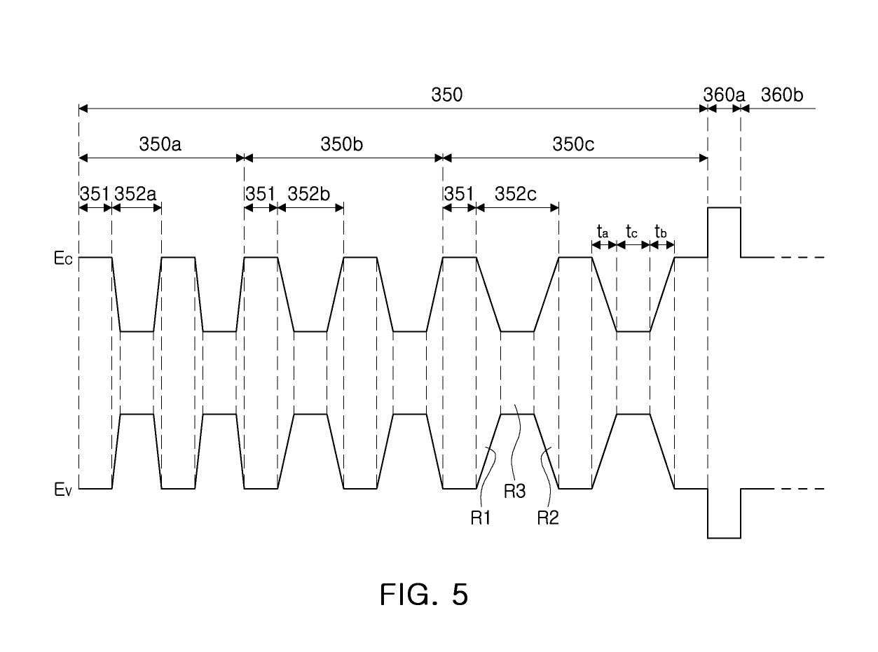

FIG. 5 is a schematic view of an energy band diagram around an active layer 350 of a semiconductor light emitting device 100 according to an example embodiment of the present inventive concept. FIG. 5 is an example of a structure of an active layer 350 different from that of the active layer 150 of the semiconductor light emitting device illustrated in FIG. 3.

Referring to FIG. 5, unlike the example embodiment illustrated in FIG. 3, the active layer 350 may include a plurality of quantum barrier layers 351 and a plurality of quantum well layers 352, and the plurality of quantum well layers 352 may be divided into three groups 352a, 352b, and 352c in which a first graded layer R1 and a second graded layer R2 have different thicknesses tₐ and t_{b}, respectively. Thicknesses of the quantum well layers 352 may be substantially the same as each other within the respective groups 352a, 352b, and 352c, but the thicknesses of the quantum well layers 352 may be greater in the group closer to an EBL 360a. Here, the thicknesses tₐ and t_{b} of the first and second graded layers R1 and R2 may be substantially the same as each other within the respective groups 352a, 352b, and 352c, but the thicknesses tₐ and t_{b} of the first and second graded layers R1 and R2 may be greater in the group closer to the EBL 360a. The thickness tₐ of the first graded layer R1 and the thickness t_{b} of the second graded layer R2 may have the same thickness as each other in the respective groups 352a, 352b, and 352c. An energy band (for example, a conduction band) of the first graded layer R1 may have a first slope at which an energy band gap is decreased in a direction toward the EBL 360a, an energy band of the second graded layer R2 may have a second slope at which an energy band gap is increased in the direction toward the EBL 360a, and the first and second slopes may be reduced in the group closer to the EBL 360a. Here, absolute values of the first and second slopes may be the same as each other. Each of the groups 352a, 352b, and 352c is illustrated as including two of the quantum well layers 352, but may include three or more quantum well layers. The respective groups 352a, 352b, and 352c may have different numbers of quantum well layers, respectively. The quantum well layers 352 may also be divided into the three groups, but the present inventive concept is not limited thereto.

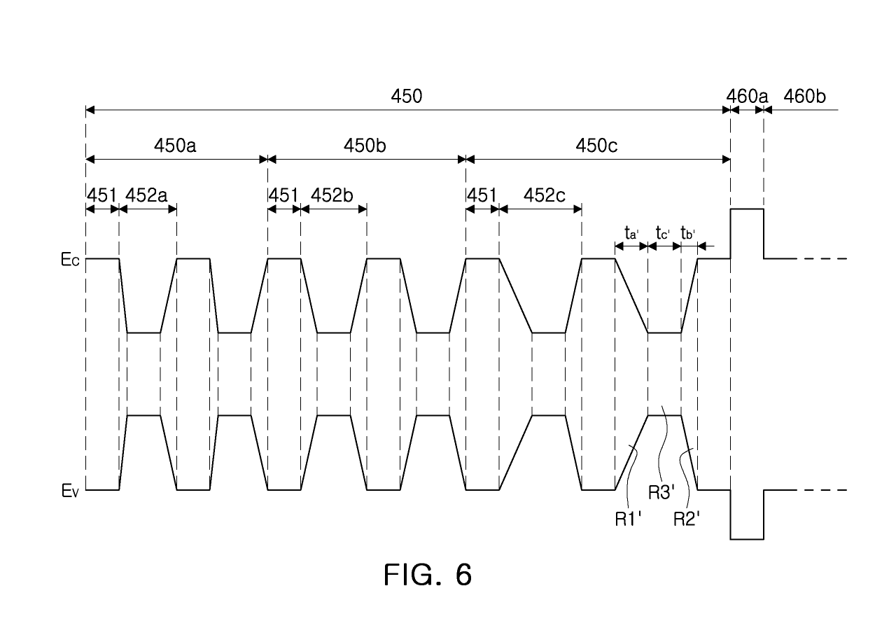

FIG. 6 is a schematic view of an energy band diagram around an active layer 450 of a semiconductor light emitting device 100 according to an example embodiment of the present inventive concept. FIG. 6 is an example of a structure of each of quantum well layers 452 within an active layer 450, the structure modified from that of each of the quantum well layers 352 within the active layer 350 of the semiconductor light emitting device illustrated in FIG. 5.

Referring to FIG. 6, the active layer 450 may include a plurality of quantum barrier layers 451 and a plurality of quantum well layers 452, and the plurality of quantum well layers 452 may be divided into three groups 452a, 452b, and 452c in which first graded layers R1′ have different thicknesses tₐ′, respectively.

A first slope of an energy band of each first graded layer R1′ may be reduced in the group closer to the EBL 460a, and a second slope of an energy band of each second graded layer R2′ may be maintained. A thickness tₐ′ of each first graded layer R1′ may be greater in the group closer to an EBL 460a, and a thickness t_{b}′ of each second graded layer R2′ may be constant. As the first and second graded layers R1′ and R2′ are closer to the EBL 460a, a slope of an In composition of each first graded layer R1′ may be reduced, and a slope of an In composition of the second graded layer R2′ may be constant.

The present inventive concept is not limited thereto, and unlike those illustrated in FIG. 6, in an example embodiment, the thicknesses t_{b}′ of the second graded layers R2′ may be different from each other in the three groups 452a, 452b, and 452c. The second slope of the energy band of each second graded layer R2′ may be reduced in the group closer to the EBL 460a, and the first slope of the energy band of each first graded layer R1′ may be maintained. In the group closer to an EBL 460a, the thickness t_{b}′ of each second graded layer R2′ may be greater, and the thickness tₐ′ of the first graded layer R1′ may be constant. As the first and second graded layers R1′ and R2′ are closer to the EBL 460a, the slope of the In composition of the second graded layer R2′ may be reduced, and the slope of the In composition of the first graded layer R1′ may be constant.

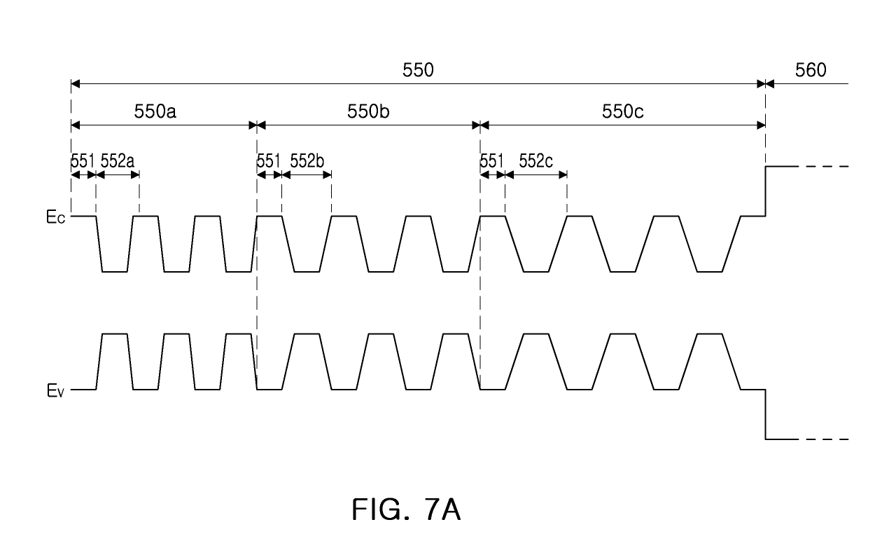

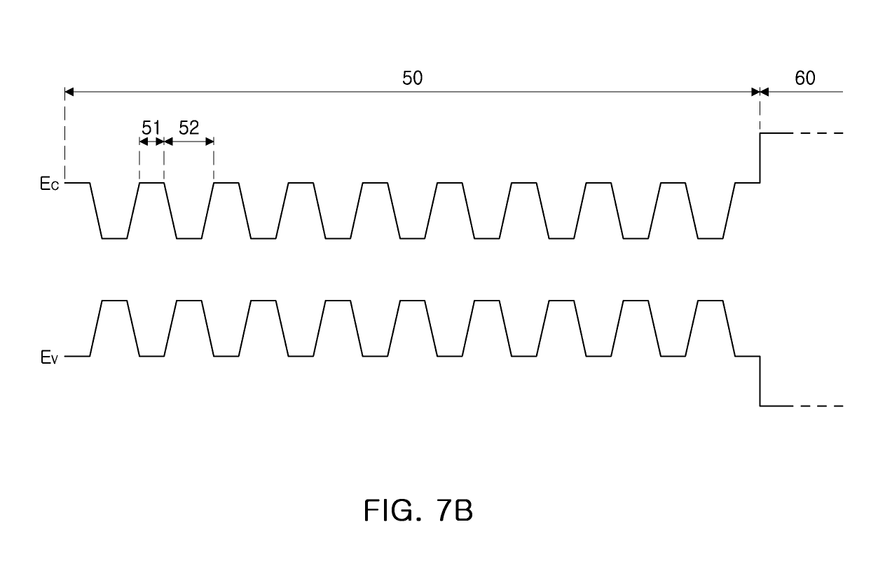

FIG. 7A is a schematic view of an energy band diagram of a semiconductor light emitting device 100 according to an example embodiment of the present inventive concept. FIG. 7B is a schematic view of an energy band diagram of a semiconductor light emitting device of the related art as a comparative example.

FIG. 7A depicts a structure similar to a semiconductor light emitting device 100 illustrated in FIG. 6, in which an active layer 550 may be divided into three groups 550a, 550b, and 550c, and each of the groups 550a, 550b, 550c may include three sets of quantum well layers 552a, 552b, 552c having different structures, respectively.

FIG. 7B is a semiconductor light emitting device (comparative example) having an active layer 50 including nine quantum well layers 52 which have the same structure as the quantum well layers 552b belonging to the second group 550b of FIG. 7A.

As a result of a chip test in the example embodiment and the comparative example, it was confirmed that optical output (based on 120 mA) of the semiconductor light emitting device was improved by 1.1% and efficiency droop thereof (based on from 65 mA to 320 mA) was enhanced by 2%, as compared to the comparative example.

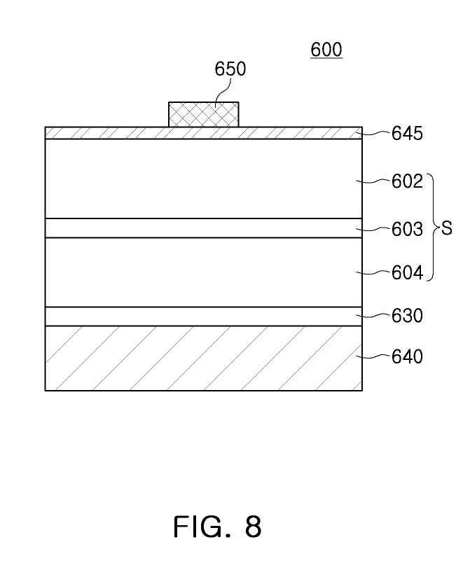

FIG. 8 is a cross-sectional view of a semiconductor light emitting device according to an example embodiment of the present inventive concept.

A semiconductor light emitting device 600 illustrated in FIG. 8 may further include a conductive support substrate 640, a bonding layer 630, a light emitting stack S, a transparent electrode layer 645, and a first electrode 650.

The light emitting stack (S) may include a second conductivity-type semiconductor layer 604, an active layer 603, and a first conductivity-type semiconductor layer 602 sequentially disposed on the conductive support substrate 640.

The first conductivity-type semiconductor layer 602 may be a nitride semiconductor layer satisfying n-type InₓAl_{y}Ga_{1-x-y}N (0≦x<1, 0≦y<1, 0≦x+y<1), and an n-type impurity may be Si. The second conductivity-type semiconductor layer 604 may be a nitride semiconductor layer satisfying p-type InₓAl_{y}Ga_{1-x-y}N (0≦x<1, 0≦y<1, 0≦x+y<1), and a p-type impurity may be Mg. The active layer 603 may have an MQW structure in which quantum well layers and quantum barrier layers are alternately stacked on each other. For example, the quantum well layers and the quantum barrier layers may be InₓAl_{y}Ga_{1-x-y}N (0≦x≦1, 0≦y≦1, 0≦x+y≦1) having different compositions. The active layer 603 may include the quantum well layers according to the example embodiments described above with reference to FIGS. 1 through 7B.

The bonding layer 630 may be provided between the conductive support substrate 640 and the second conductivity-type semiconductor layer 604. The bonding layer 630 may be formed using an alloy having a eutectic temperature of 200° C. or more. For example, the bonding layer 630 may be formed using an AuSn alloy (a eutectic temperature of about 280° C.), an AuGe alloy (a eutectic temperature of about 350° C.) or an AuSi alloy (a eutectic temperature of about 380° C.). The conductive support substrate 640 may include one of materials such as Si, SiAl, SiC, GaP, InP, AlN, and graphite.

The transparent electrode layer 645 disposed on the first conductivity-type semiconductor layer 602 may be selectively adopted. The transparent electrode layer 645 may be in ohmic contact with the first conductivity-type semiconductor layer 602, and may transmit light emitted by the light emitting stack S. An ohmic contact material that may be in ohmic contact with the first conductivity-type semiconductor layer 602 may include at least one of Ag, Ni, Al, Rh, Pd, Ir, Ru, Mg, Zn, Pt, and Au, and may have a structure having a single layer or multiple layers. The transparent electrode layer 645 may also be one of a transparent conductive oxide layer or a nitride layer, and for example, may contain at least one selected from the group consisting of ITO, ZITO, ZIO, GIO, ZTO, FTO, AZO, GZO, In₄Sn₃O₁₂ or Zn₍₁₋ₓ₎MgₓO (0≦x≦1). If necessary, the transparent electrode layer 645 may also contain graphene.

The first electrode 645 disposed on the transparent electrode layer 645 may contain a material such as Ag, Ni, Al, Cr, Rh, Pd, Ir, Ru, Mg, Zn, Pt, or Au, and may be employed as a structure having a single layer or two or more layers.

The semiconductor light emitting device 600 may include an unevenness structure on a light emitting surface provided by the first conductivity-type semiconductor layer 602. The unevenness structure may be effective to externally extract light emitted by the active layer 603 by reducing total internal reflection.

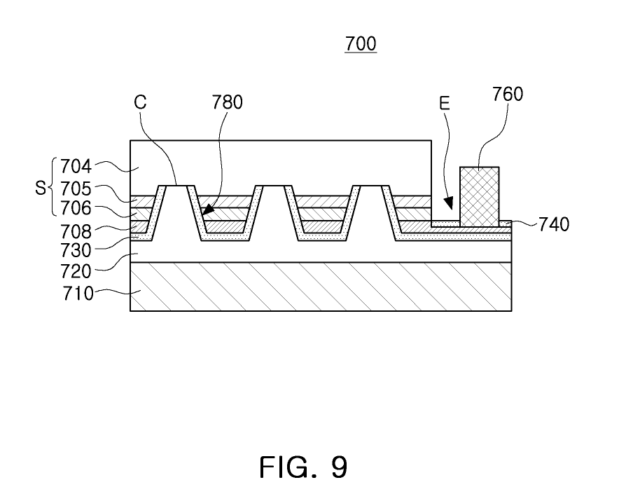

FIG. 9 is a cross-sectional view of a semiconductor light emitting device according to an example embodiment of the present inventive concept.

A semiconductor lighting emitting device 700 illustrated in FIG. 9 may have a large area structure for high output for lighting use. The semiconductor lighting emitting device 700 may have a structure for increasing current distribution efficiency and heat dissipation efficiency.

The semiconductor lighting emitting device 700 may include a light emitting stack S, a first electrode 720, an insulating layer 730, a second electrode 708, and a substrate 710. The light emitting laminate S may include a first conductivity-type semiconductor layer 704, an active layer 705, and a second conductivity-type semiconductor layer 706 stacked sequentially. The active layer 705 may include the quantum well layers according to the example embodiments described above with reference to FIGS. 1 through 7B.

The first electrode 720 may include at least one conductive via 780 electrically insulated from the second conductivity-type semiconductor layer 706 and the active layer 705 and extending to at least a portion of the first conductivity-type semiconductor layer 704 to be electrically connected to the first conductivity-type semiconductor layer 704. The at least one conductive via 780 may extend from an interface of the first electrode 720 to an inside of the first conductivity-type semiconductor layer 704 through the second electrode 708, the second conductivity-type semiconductor layer 706, and the active layer 705. The at least one conductive via 780 may be formed using a dry etching process, such as inductively coupled plasma-reactive ion etching (ICP-RIE) or the like.

The first electrode 720 may include the insulating layer 730 provided thereon to electrically insulate the first electrode 720 from a region different from the substrate 710 and the first conductivity-type semiconductor layer 704. The insulating layer 730 may be formed on a lateral side of the at least one conductive via 780 as well as in a space between the second electrode 708 and the first electrode 720. This may allow the first electrode 720 to be insulated from the second electrode 708, the second conductivity-type semiconductor layer 706, and the active layer 705, exposed to the lateral side of the at least one conductive via 780. The insulating layer 730 may be formed by depositing an insulating material such as SiO₂, SiOₓN_{y}, or SiₓN_{y}.

A contact area C of the first conductivity-type semiconductor layer 704 may be exposed through the at least one conductive via 780, and a portion of the first electrode 720 may contact the contact area C through the at least one conductive via 780. This may allow the first electrode 720 to be connected to the first conductivity-type semiconductor layer 704.

The at least one conductive via 780 may be controlled in number, shape, pitch, contact diameter (or contact area) in such a manner that contact resistance thereto may be reduced. The at least one conductive via 780 may be arranged in various forms in rows and columns, and thus current flow of the semiconductor lighting emitting device 700 may be improved.

The second electrode 708 may extend externally from the light emitting stack S as illustrated in FIG. 9 to provide an exposed electrode formation area E. The electrode formation area E may include an electrode pad portion 760 for connecting an external power source to the second electrode 708. The electrode formation area E may be exemplified in singular, but may be provided in plural if necessary. The electrode formation area E may be formed on an edge of a side of the semiconductor light emitting device 700 to significantly increase a light emitting area thereof.

As in the example embodiment, an insulating layer 740 for etching stop may be disposed around the electrode pad portion 760. The insulating layer 740 for etching stop may be formed on the electrode formation area E after the formation of the light emitting stack S and before the formation of the second electrode 708, and may function as an etching stopper in an etching process for the electrode formation area E.

The second electrode 708 may be formed using a material having high reflectivity while being in ohmic contact with the second conductivity-type semiconductor layer 706. The reflective electrode material previously exemplified may be used as the material for the second electrode 708.

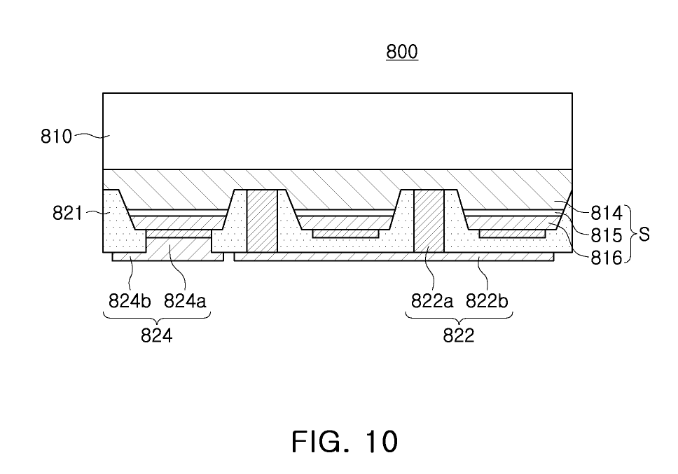

FIG. 10 is a cross-sectional view of a semiconductor light emitting device according to an example embodiment of the present inventive concept.

Referring to FIG. 10, a semiconductor light emitting device 800 may include a light emitting stack S formed on a substrate 810. The light emitting stack S may include a first conductivity-type semiconductor layer 814, an active layer 815, and a second conductivity-type semiconductor layer 816. The active layer 815 may include quantum well layers according to the example embodiments described above with reference to FIGS. 1 through 7B.

The semiconductor light emitting device 800 may include a first electrode 822 and a second electrode 824 respectively connected to the first conductivity-type semiconductor layer 814 and the second conductivity-type semiconductor layer 816. The first electrode 822 may include a connecting electrode portion 822a, such as a conductive via, passing through the second conductivity-type semiconductor layer 816 and the active layer 815 to be connected to the first conductivity-type semiconductor layer 814, and a first electrode pad 822b connected to the connecting electrode portion 822a. The connecting electrode portion 822a may be surrounded by insulating portions 821 to be electrically separated from the active layer 815 and the second conductivity-type semiconductor layer 816. The connecting electrode portion 822a may be disposed on an area from which the light emitting stack S is etched. The connecting electrode portion 822a may be properly designed in number, shape, pitch or contact area with the first conductivity-type semiconductor layer 814 in such a manner that contact resistance to the connecting electrode portion 822a may be reduced. The connecting electrode portions 822a may also be arranged to form rows and columns on the semiconductor stack S, thereby improving current flow of the semiconductor light emitting device 800. The second electrode 824 may include an ohmic contact layer 824a disposed on the second conductivity-type semiconductor layer 816 and a second electrode pad 824b disposed above the second conductivity-type semiconductor layer 816.

The connecting electrode portion 822a and the ohmic contact layer 824a may have a structure having a single layer or multiple layers, the structure formed of the first and second conductivity-type semiconductor layers 814 and 816 and a conductive material having ohmic characteristics. For example, the connecting electrode portion 822a and the ohmic contact layer 824a may be formed using a process of depositing, or the like, at least one of materials such as Ag, Al, Ni, Cr, or a transparent conductive oxide (TCO).

The first and second electrode pads 822b and 824b may be connected to the connecting electrode portions 822a and the ohmic contact layer 824a, respectively, to function as an external terminal of the semiconductor light emitting device 800. For example, the first and second electrode pads 822b and 824b may contain Au, Ag, Al, Ti, W, Cu, Sn, Ni, Pt, Cr, NiSn, TiW, AuSn, or eutectic metals thereof.

The first and second electrodes 822 and 824 may be disposed with each other in an identical direction, and may be mounted on a lead frame or the like in a so-called flip-chip form.

In addition, the two first and second electrodes 822 and 824 may be electrically separated from each other by the insulating portions 821. The insulating portion 821 may be formed using any material having electrically insulating characteristics, any object having electrically insulating characteristics, but a material having low optical absorption. For example, a silicon oxide such as SiO₂ and a silicon nitride such as SiOₓN_{y} or SiₓN_{y} may be used. If necessary, a light-reflective structure may be formed by dispersing a light-reflective filler in a light transmitting material. In a different manner, the insulating portions 821 may have a multilayer reflective structure in which a plurality of insulating films having respective different refractive indexes are alternately stacked. For example, the multilayer reflective structure may be a distributed Bragg reflector (DBR) in which a first insulating film having a first refractive index and a second insulating film having a second refractive index are alternately stacked.

The multilayer reflective structure may have the plurality of insulating films having the different refractive indexes and repeatedly stacked from 2 to 100 times. For example, the plurality of insulating films may be repeatedly stacked from 3 to 70 times, and further from 4 to 50 times. Each of the plurality of insulating films included in the multilayer reflective structure may be an oxide such as SiO₂, TiO₂, Al₂O₃, or ZrO₂, a nitride such as SiN, Si₃N₄, TiN, AlN, TiAlN, or TiSiN, and a combination thereof such as SiOₓN_{y}. For example, when a wavelength of light generated by the active layer 815 is defined as k, and n is defined as a refractive index of a corresponding layer, the first and second insulating films may each have a thickness of λ/4n, and for example, may each have a thickness of about 300 Å to about 900 Å. In this case, the multilayer reflective structure may be designed by selecting refractive indexes and thicknesses of the first and second insulating films, respectively, to have high reflectivity (95% or more) for the wavelength of light generated by the active layer 415.

A light emitting diode (LED) chip package having a chip-scale package (CSP) structure may be used as an example of a light emitting device package. The CSP structure may allow for reduction in a size of the LED chip package and simplification of a manufacturing process thereof, thereby being suitable for use in mass production, and may enable a wavelength conversion material such as a phosphor and an optical structure such as a lens to be integrated with an LED chip, thereby being particularly used to suit a lighting device.

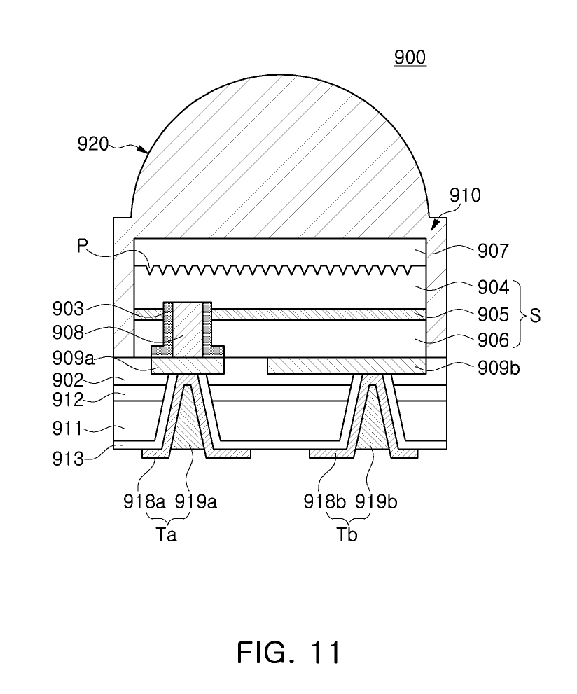

FIG. 11 is a cross-sectional view of a chip-scale light emitting device package including a semiconductor light emitting device according to an example embodiment of the present inventive concept.

Referring to FIG. 11, a light emitting device package 900 may include a light emitting stack S disposed above a mounting substrate 911, a first terminal Ta, a second terminal Tb, a phosphor layer 907, and a lens 920. The light emitting device package 900 may have electrodes formed on a lower surface of a semiconductor lighting emitting device 910 positioned in a direction opposite to a primary light extracting surface, and may have the phosphor layer 907 and the lens 920 integrated with each other.

The light emitting stack S may have a structure in which a first conductivity-type semiconductor layer 904, a second conductivity-type semiconductor layer 906, and an active layer 905 disposed therebetween are stacked on each other. In the example embodiment, the first and second conductivity-type semiconductor layers 904 and 906 may be provided as n- and p-type semiconductor layers, respectively, and may include a nitride semiconductor, such as AlₓIn_{y}Ga_{1-x-y}N (0<x<1, 0<y<1, 0<x+y<1).

The active layer 905 formed between the first and second conductivity-type semiconductor layers 904 and 906 may emit light having a predetermined level of energy by a recombination of electrons and holes, and may have an MQW structure in which quantum well layers and quantum barrier layers are alternatively stacked on each other. The active layer 905 may include quantum well layers according to the example embodiments described above with reference to FIGS. 1 through 7B.

The semiconductor light emitting device 910 may remain in a state in which a growth substrate is removed therefrom, and may have an unevenness pattern P formed on a surface from which the growth substrate is eliminated. The phosphor layer 907 as a light conversion layer may also be disposed on the surface on which the unevenness pattern P is formed. The growth substrate may not be removed, and the unevenness pattern P and the light conversion layer may be formed on a rear surface of the growth substrate. The semiconductor light emitting device 910 may include a first electrode 909a and a second electrode 909b respectively connected to the first conductivity-type semiconductor layer 904 and the second conductivity-type semiconductor layer 906. The first electrode 909a may include a conductive via 908 passing through the second conductivity-type semiconductor layer 906 and the active layer 905 to be connected to the first conductivity-type semiconductor layer 904. The conductive via 908 may be prevented from being short-circuited by an insulating layer 903 formed between the active layer 905 and the second conductivity-type semiconductor layer 906.

The conductive via 908 may be exemplified in singular, but may be provided in plural to promote current distribution, and may be arranged in various forms.

The mounting substrate 911 employed in the example embodiment may be a support substrate readily applied to a semiconductor process, such as a silicon substrate, but is not limited thereto. The mounting substrate 911 and the semiconductor light emitting device 910 may be bonded to each other by bonding layers 902 and 912. The bonding layers 902 and 912 may include an electrically insulating material or an electrically conductive material. For example, the electrically insulating material may include an oxide such as SiO₂ or SiN, a resin material such as a silicon resin or an epoxy resin, or the like, and the electrically conductive material may include Ag, Al, Ti, W, Cu, Sn, Ni, Pt, Cr, NiSn, TiW, AuSn, or eutectic metals thereof. According to an example embodiment, the first and second electrodes 909a and 909b may be connected to the first and second terminals Ta and Tb of the mounting substrate 811, respectively, without the bonding layers 902 and 912. As another example, the first and second electrodes 909a and 909b may include a plurality of metallic layers, respectively, for example, an under bump metallurgy (UBM) layer and a solder bump. In this case, the mounting substrate 911, the bonding layers 902 and 912, and the first and second terminals Ta and Tb may also be removed.

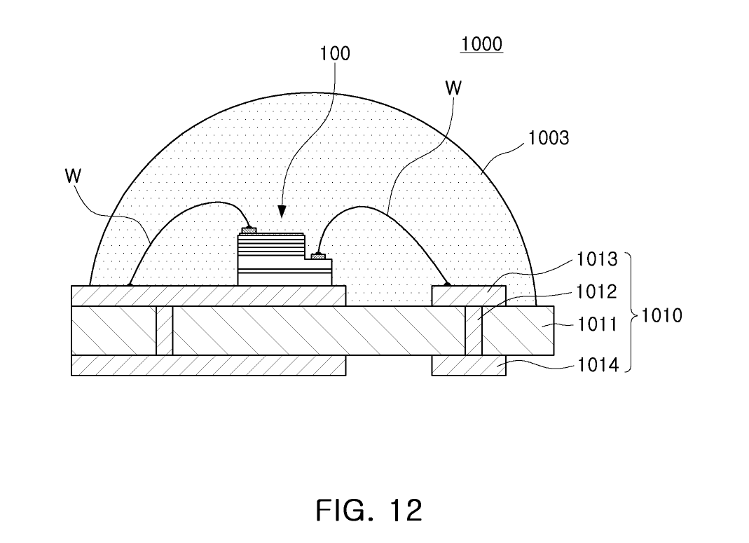

FIG. 12 is a cross-sectional view of a light emitting device package including a semiconductor light emitting device according to an example embodiment of the present inventive concept.

A light emitting device package 1000 illustrated in FIG. 12 may include the semiconductor light emitting device 100 illustrated in FIG. 1, a mounting substrate 1010, and an encapsulant 1003. The semiconductor light emitting device 100 may be disposed on the mounting substrate 1010 to be electrically connected to the mounting substrate 1010 by a wire W. The mounting substrate 1010 may include a substrate body 1011, an upper electrode 1013, a lower electrode 1014, and a through electrode 1012 connecting the upper electrode 1013 to the lower electrode 1014. The substrate body 1011 may include a resin, a ceramic, or a metal, and the upper or lower electrode 1013 and 1014 may be a metallic layer such as Au, Cu, Ag, or Al. For example, the mounting substrate 1010 may be provided as a substrate, such as a printed circuit board (PCB), a metal core printed circuit board (MCPCB), a metal printed circuit board (MPCB), or a flexible printed circuit board (FPCB), and a structure of the mounting substrate 1010 may be applied in various forms.

The encapsulant 1003 may have a dome-shaped lens structure having a convex upper surface, according to an example embodiment, and may include a surface having a convex or concave lens structure, thereby allowing an orientation angle of light emitted through an upper surface of the encapsulant 703 to be adjusted.

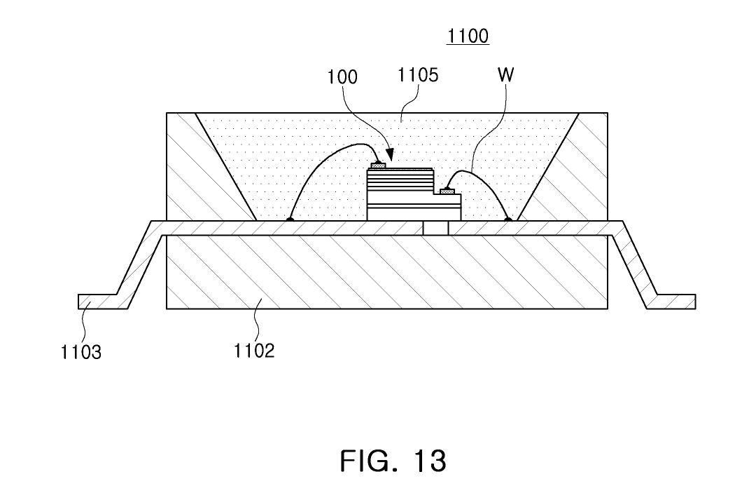

FIG. 13 is a cross-sectional view of a light emitting device package including a semiconductor light emitting device according to an example embodiment of the present inventive concept.

A semiconductor light emitting device package 1100 illustrated in FIG. 13 may include the semiconductor light emitting device 100 illustrated in FIG. 1, a package body 1102, and a pair of lead frames 1103.

The semiconductor light emitting device 100 may be disposed on the pair of lead frames 1103, and respective electrodes of the semiconductor light emitting device 100 may be electrically connected to the pair of lead frames 1103 by a wire W. If necessary, the semiconductor light emitting device 100 may be disposed in a region different from the lead frames 1103, such as on the package body 1102. In addition, the package body 1102 may have a recess portion having a cup shape so that light reflection efficiency may be increased, and the recess portion may be filled with an encapsulant 1105 including a light transmitting material to encapsulate the semiconductor light emitting device 100, the wire W, and the like.

The encapsulant 1105 may contain a wavelength conversion material such as a phosphor and/or a quantum dot, if necessary. The wavelength conversion material will be described below in more detail.

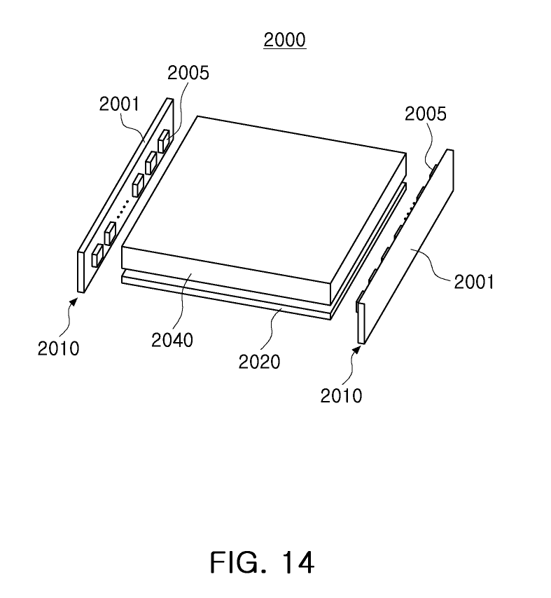

FIG. 14 is a perspective view of a backlight unit including a semiconductor light emitting device according to an example embodiment of the present inventive concept.

Referring to FIG. 14, a backlight unit 2000 may include a light guide plate 2040 and light source modules 2010 provided on opposing side surfaces thereof, respectively. The backlight unit 2000 may also further include a reflector 2020 disposed below the light guide plate 2040. The backlight unit 2000 according to the example embodiment may be an edge-type.

According to an example embodiment, the light source modules 2010 may be provided only on a side surface of the light guide plate 2040, or additionally on another side surface thereof. The light source module 2010 may include a PCB 2001 and a plurality of light sources 2005 disposed on an upper surface of the PCB 2001. Here, the light sources 2005 may include a semiconductor light emitting device according to an example embodiment.

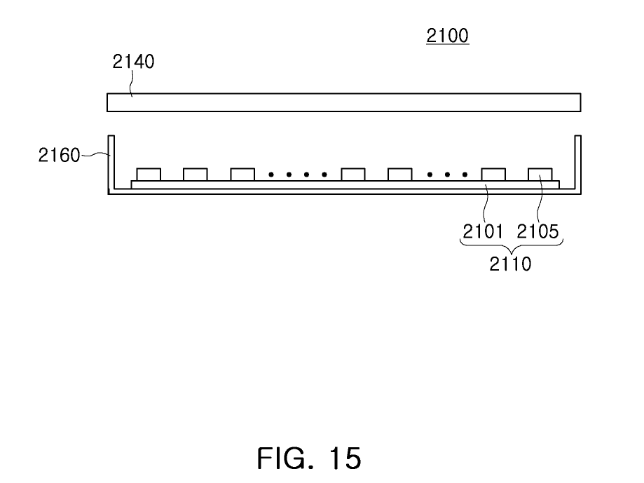

FIG. 15 is a cross-sectional view of a direct-type backlight unit including a semiconductor light emitting device according to an example embodiment of the present inventive concept.

Referring to FIG. 15, a backlight unit 2100 may include a light diffusion plate 2140 and a light source module 2110 disposed below the light diffusion plate 2140. The backlight unit 2100 may also further include a bottom case 2160 disposed below the light diffusion plate 2140 and accommodating the light source module 2110. The backlight unit 2100 according to the example embodiment may be a direct-type.

The light source module 2110 may include a PCB 2101 and a plurality of light sources 2105 disposed on an upper surface of the PCB 2101. Here, the light sources 2105 may include a semiconductor light emitting device according to an example embodiment.

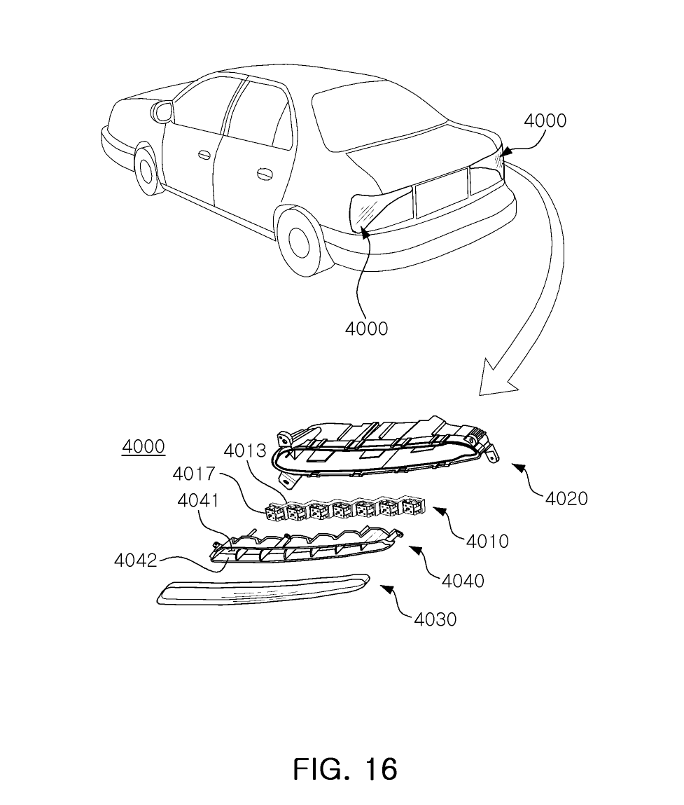

FIG. 16 is a schematic view of a lighting device in which a light source module according to an example embodiment of the present inventive concept is adopted. The lighting device according to the example embodiment may include, for example, rear lamps of a vehicle.

Referring to FIG. 16, a lighting device 4000 may include a housing 4020 supporting a light source module 4010, and a cover 4030 covering the housing 4020 to protect the light source module 4010, and a reflector 4040 may be disposed on the light source module 4010. The reflector 4040 may include a plurality of reflective surfaces 4041 and a plurality of through holes 4042 provided on respective bottom surfaces of the plurality of reflective surfaces 4041. A plurality of light emitting units 4017 of the light source module 4010 may be exposed to the reflective surfaces 4041 through the through holes 4042, respectively.

The lighting device 4000 may have an overall gently curved structure to correspond to a shape of a corner portion of a vehicle. Thus, the light emitting unit 4017 may be attached to a frame 4013 to match the curved structure of the lighting device 4000, thereby forming the light source module 4010 having a step structure corresponding to the curved structure. Such a structure of the light source module 4010 may be variously modified depending on designs of the lighting device 4000, for example, rear lamps. This may also allow the number of light emitting units 4017 attached to the frame 4013 to be changed.

In the example embodiment, the lighting device 4000 is exemplified as the rear lamps of the vehicle, but the present inventive concept is not limited thereto. For example, the lighting device 4000 may include headlamps of a vehicle and turn signal lamps mounted in door mirrors of a vehicle. In this case, the light source module 4010 may have a multistep structure corresponding to curved surfaces of the headlamps and the turn signal lamps.

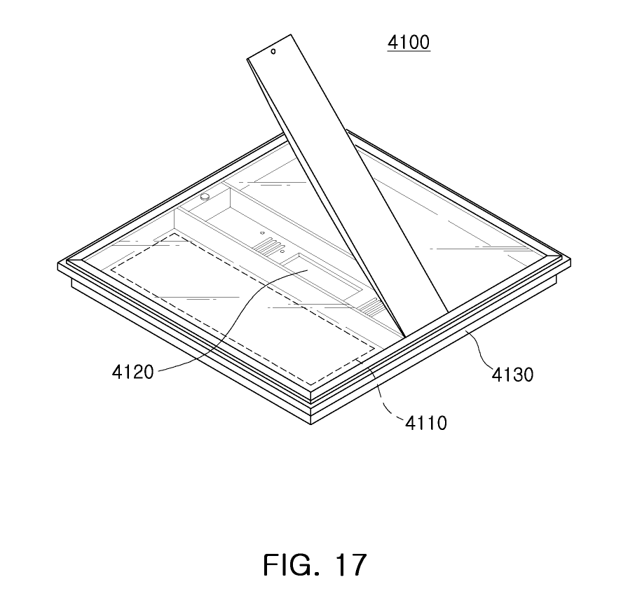

FIG. 17 is a perspective view of a flat panel lighting device including a semiconductor light emitting device according to an example embodiment of the present inventive concept.

Referring to FIG. 17, a flat panel lighting device 4100 may include a light source module 4110, a power supply 4120, and a housing 4130. According to an example embodiment, the light source module 4110 may include a light emitting device array as a light source, and the power supply 4120 may include a light emitting device driver.

The light source module 4010 may include the light emitting device array, and may have an overall flat shape. The light emitting device array may include a light emitting device and a controller storing driving information of the light emitting device. The light emitting device may be a semiconductor light emitting device according to an example embodiment.

The power supply 4120 may be configured to supply power to the light source module 4110. The housing 4130 may have a space to receive the light source module 4110 and the power supply 4120 therein, and may have a hexahedral shape with an open side surface thereof, but is not limited thereto. The light source module 4110 may be disposed to emit light to the open side surface of the housing 4130.

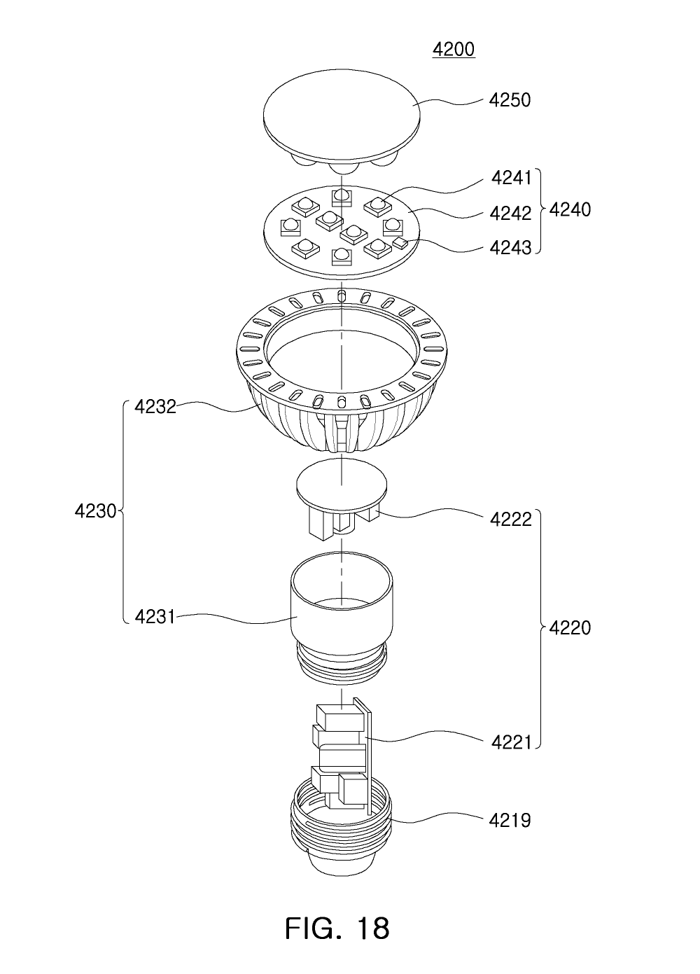

FIG. 18 is an exploded perspective view of a lamp including a semiconductor light emitting device according to an example embodiment of the present inventive concept.

Referring to FIG. 18, a lighting device 4200 may include a socket 4219, a power supply 4220, a heat sink 4230, a light source module 4240, and an optical unit 4250. The light source module 4240 may include a light emitting device array, and the power supply 4220 may include a light emitting device driver.

The socket 4219 may be configured to replace that of a conventional lighting device. Power supplied to the lighting device 4200 may be applied through the socket 4219. As illustrated in FIG. 18, the power supply 4220 may be separately attached with a first power supply 4221 and a second power supply 4222. The heat sink 4230 may include an internal heat sink 4231 and an external heat sink 4232. The internal heat sink 4231 may be directly connected to the light source module 4240 and/or the power supply 4220. This may allow heat to be transferred to the external heat sink 4232. The optical unit 4250 may include an internal optical portion (not shown) and an external optical portion (not shown), and may be configured to evenly scatter light emitted by the light source module 4240.

The light source module 4240 may receive power from the power supply 4220 to emit light to the optical unit 4250. The light source module 4240 may include at least one light emitting device 4241, a circuit board 4242, and a controller 4243, and the controller 4243 may store driving information of the at least one light emitting device 4241. The at least one light source 4241 may be a semiconductor light emitting device according to an example embodiment.

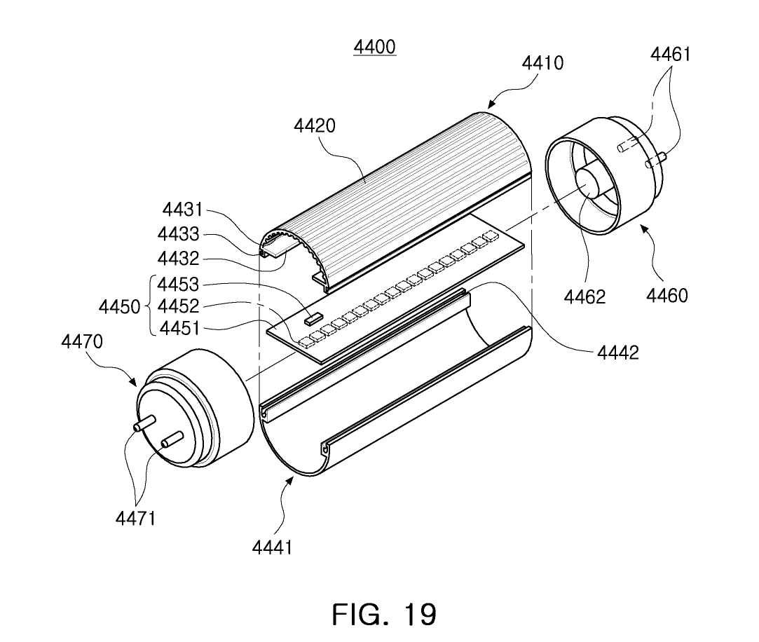

FIG. 19 is an exploded perspective view of a bar-type lamp including a semiconductor light emitting device according to an example embodiment of the present inventive concept.

Referring to FIG. 19, a lighting device 4400 may include a heat sink 4410, a cover 4441, a light source module 4450, a first socket 4460, and a second socket 4470. A plurality of heat sink fins 4420 and 4431 may have an uneven shape on internal or/and external surfaces of the heat sink 4410, and may be designed to have various shapes and intervals. The heat sink 4410 may have protruding supports 4432 formed on an inside thereof. The protruding supports 4432 may be fixed to the light source module 4450. The heat sink 4410 may have protrusions 4433 respectively formed on opposing ends thereof.

The cover 4441 may have grooves 4442 formed therein, and the protrusions 4433 of the heat sink 4410 may be coupled to the grooves 4442 by a hook coupling structure, respectively. Locations of the grooves 4442 and the protrusions 4433 may be reversed with each other.

The light source module 4450 may include a light emitting device array. The light source module 4450 may include a PCB 4451, light sources 4452, and a controller 4453. The controller 4453 may store driving information of the light sources 4452. The PCB 4451 may have circuit lines formed thereon to operate the light sources 4452. The PCB 4451 may also include components for operating the light sources 4452. The light sources 4452 may include a semiconductor light emitting device according to an example embodiment.

The first and second sockets 4460 and 4470 may have a structure in which the first and second sockets 4460 and 4470 may be coupled to both ends of a cylindrical cover unit including the heat sink 4410 and the cover 4441 as a pair of sockets. For example, the first socket 4460 may include electrode terminals 4461 and a power supply 4462, and the second socket 4470 may include dummy terminals 4471 disposed thereon. In addition, one of the first and second sockets 4460 and 4470 may have an optical sensor and/or a communications module built therein. For example, the second socket 4470 having the dummy terminals 4471 disposed thereon may have an optical sensor and/or a communications module built therein. As another example, the first socket 4460 having the electrode terminals 4461 disposed thereon may have an optical sensor and/or a communications module built therein.

As set forth above, according to an example embodiment of the present inventive concept, optical output and efficiency droop of a semiconductor light emitting device may be improved.

While exemplary embodiments have been shown and described above, it will be apparent to those skilled in the art that modifications and variations could be made without departing from the scope of the present inventive concept as defined by the appended claims.

1. A semiconductor light emitting device comprising:
a first conductivity-type semiconductor layer;
an active layer disposed on the first conductivity-type semiconductor layer, and comprising:
a plurality of quantum barrier layers; and
a plurality of quantum well layers containing indium (In), the plurality of quantum barrier layers and the plurality of quantum well layers being alternately stacked on each other, the plurality of quantum well layers comprising a first quantum well layer and a second quantum well layer; and
a second conductivity-type semiconductor layer disposed on the active layer,
wherein the first quantum well layer is disposed closer to the first conductivity-type semiconductor layer than the second quantum well layer, wherein the second quantum well layer is disposed closer to the second conductivity-type semiconductor layer than the first quantum well layer, wherein a thickness of the second quantum well layer is greater than a thickness of the first quantum well layer, and wherein each of the first and the second quantum well layers comprises at least one graded layer having a varying amount of In composition, and the at least one graded layer of the second quantum well layer has a greater thickness than the at least one graded layer of the first quantum well layer.

2. The semiconductor light emitting device of claim 1, wherein each of the first and the second quantum well layers comprises:
a first graded layer having an increasing amount of an In composition in a direction toward the second conductivity-type semiconductor layer; and
a second graded layer having a decreasing amount of an In composition in a direction toward the second conductivity-type semiconductor layer,
wherein at least one of the first graded layer and the second graded layer of the second quantum well layer has a greater thickness than corresponding one of the first graded layer and the second graded layer of the first quantum well layer.

3. The semiconductor light emitting device of claim 2, wherein the first graded layer and the second graded layer of the second quantum well layer have greater thicknesses than the first graded layer and the second graded layer of the first quantum well layer, respectively.

4. The semiconductor light emitting device of claim 3, wherein a thickness of the first graded layer of the first quantum well layer is equal to a thickness of the second graded layer of the first quantum well layer, and
wherein a thickness of the first graded layer of the second quantum well layer is equal to a thickness of the second graded layer of the second quantum well layer.

5. The semiconductor light emitting device of claim 2, wherein a thickness of the first graded layer of the second quantum well layer is greater than a thickness of the first graded layer of the first quantum well layer, and
wherein a thickness of the second graded layer of the first quantum well layer is equal to a thickness of the second graded layer of the second quantum well layer.

6. The semiconductor light emitting device of claim 2, wherein a thickness of the second graded layer of the second quantum well layer is greater than a thickness of the second graded layer of the first quantum well layer, and
wherein a thickness of the first graded layer of the first quantum well layer is equal to a thickness of the first graded layer of the second quantum well layer.

7. The semiconductor light emitting device of claim 2, wherein each of the first and the second quantum well layers further comprises an internal quantum well layer having a constant In composition and disposed between the first graded layer and the second graded layer of each of the first and the second quantum well layers.

8. The semiconductor light emitting device of claim 7, wherein a thickness of the internal quantum well layer of the first quantum well layer is equal to a thickness of the internal quantum well layer of the second quantum well layer.

9. The semiconductor light emitting device of claim 7, wherein a thickness of the internal quantum well layer of the second quantum well layer is less than a thickness of the internal quantum well layer of the first quantum well layer.

10. The semiconductor light emitting device of claim 7, wherein the second quantum well layer is disposed closer to the second conductivity-type semiconductor layer than the first quantum well layer, and
wherein a thickness of the first graded layer of the second quantum well layer and a thickness of the second graded layer of the second quantum well layer is greater than a thickness of the internal quantum well layer of the second quantum well layer.

11. The semiconductor light emitting device of claim 7, wherein the first quantum well layer is disposed closer to the first conductivity-type semiconductor layer than the second quantum well layer, and
wherein a thickness of the first graded layer of the first quantum well layer and a thickness of the second graded layer of the first quantum well layer is smaller than a thickness of the internal quantum well layer of the second quantum well layer.

12. The semiconductor light emitting device of claim 2, wherein an energy band of the first graded layer of each of the first and the second quantum well layers has a first slope at which a band gap of the energy band is decreased in a direction toward the second conductivity-type semiconductor layer,
wherein an energy band of the second graded layer of each of the first and the second quantum well layers has a second slope at which a band gap of the energy band is increased in the direction toward the second conductivity-type semiconductor layer, and
wherein at least one of the first slope and the second slope of the second quantum well layer is smaller than at least one of the first slope and the second slope of the first quantum well layer.

13. The semiconductor light emitting device of claim 12, wherein the first slope and the second slope of the second quantum well layer are smaller than the first slope and the second slope of the first quantum well layer, and
wherein an absolute value of the first slope of the first quantum well layer is equal to an absolute value of the second slope of the first quantum well layer.

14. The semiconductor light emitting device of claim 12, wherein one of the first slope and the second slope of the second quantum well layer is smaller than corresponding one of the first slope and the second slope of the first quantum well layer, and
wherein the other of the first slope and the second slope of the second quantum well layer is equal to corresponding one of the first slope and the second slope of the first quantum well layer.

15. The semiconductor light emitting device of claim 2, wherein the plurality of quantum well layers comprises a plurality of groups, each group including a plurality of first graded layers and a plurality of second graded layers, and
wherein a thickness of one of the first graded layers and the second graded layers of a first group is different from a thickness of corresponding one of the first graded layers and the second graded layers of a second group.

16. The semiconductor light emitting device of claim 15, wherein the second group is provided closer to the second conductivity-type semiconductor layer than the first group, and
wherein the thicknesses of the first and the second graded layers of the second group are greater than the thicknesses of the first and the second graded layers of the first group.

17. The semiconductor light emitting device of claim 16, wherein in each of the groups the first graded layers and the second graded layers have the same thickness as each other.

18. The semiconductor light emitting device of claim 15, wherein
wherein a thickness of one of the first graded layers and the second graded layers of the first group is greater than a thickness of corresponding one of the first graded layers and the second graded layers of the second group, and
wherein a thickness of the other of the first graded layers and the second graded layers of the first group is equal to a thickness of corresponding one of the first graded layers and the second graded layers of the second group.

19. A semiconductor light emitting device comprising:
a first conductivity-type nitride semiconductor layer;
an active layer disposed on the first conductivity-type nitride semiconductor layer, and having a plurality of quantum barrier layers including gallium nitride (GaN) and a plurality of quantum well layers including InₓGa₁₋ₓN (0<x≦1), the plurality of quantum barrier layers and the plurality of quantum well layers alternately stacked on each other, the plurality of quantum well layers comprising a first quantum well layer and a second quantum well layer; and
a second conductivity-type nitride semiconductor layer disposed on the active layer and having an electron blocking layer (EBL) including Al_{y}Ga_{1-y}N (0<y≦1),
wherein the second quantum well layer is disposed closer to the EBL than the first quantum well layer,
wherein each of the first and the second quantum well layers comprises:
a first graded layer having an increasing amount of an In composition in a direction toward the second conductivity-type semiconductor layer; and
a second graded layer having a decreasing amount of an In composition in a direction toward the second conductivity-type semiconductor layer,
wherein at least one of the first graded layer and the second graded layer of the second quantum well layer has a greater thickness than corresponding one of the first graded layer and the second graded layer of the first quantum well layer.

20-25. (canceled)

26. A semiconductor light emitting device comprising:
an n-type nitride semiconductor layer;
an active layer disposed on the n-type nitride semiconductor layer, and having a plurality of quantum barrier layers including GaN and a plurality of quantum well layers including InₓGa₁₋ₓN (0<x≦1), the quantum barrier layers and the quantum well layers alternately stacked on each other, the plurality of quantum well layers comprising a first quantum well layer and a second quantum well layer; and
a p-type nitride semiconductor layer disposed on the active layer and having an electron blocking layer (EBL) including Al_{y}Ga_{1-y}N (0<y≦1),
wherein each of the first and the second quantum well layers comprises:
a first graded layer; and
a second graded layer, and
wherein the first graded layer of the second quantum well layer has a band gap decreased in a direction toward the EBL,
wherein a second graded layer of the second quantum well layer has a band gap increased in a direction toward the EBL, and
wherein at least one of the first graded layer and the second graded layer of the second quantum well layer has a greater thickness than corresponding one of the first graded layer and the second graded layer of the first quantum well layer.
